(19) United States
(12) Patent Application Publication
(10) Pub. No.: US 2010/0259250 A1
(43) Pub. Date: Oct. 14, 2010

(54) MAGNETIC SENSOR DEVICE ON A MICROCHIP

(75) Inventor: Josephus ARNOLDUS HENRICUS MARIA Kahlman, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/376,627

(22) PCT Filed: Jul. 10, 2007
(86) PCT No.: PCT/IB07/52740

§ 371 Date: Jun. 9, 2010

(30) Foreign Application Priority Data
Aug. 9, 2006 (EP) 06118679.7

(51) Int. Cl. H01L 43/06; H01L 43/08

(52) U.S. Cl. 324/207.2; 324/207.21

(57) ABSTRACT

The invention relates to a microelectronic magnetic sensor device that comprises at least one sensor unit (10) with a magnetic field generator (11, 13) and a magnetic sensor element (12) that are coupled to a power supply unit (20) via only two common connecting terminals (x, y). In this way, the number of bonding pins on the associated microelectronic chip can be reduced to a minimum. The sensor units (10) may preferably comprise magnetic excitation wires (11, 13) as field generator and a GMR resistance (12) as sensor element that are connected (optionally via a capacitor (14)) in parallel to the connecting terminals (x, y). The power supply unit (20) preferably supplies a driving current with two frequency components such that the information of interest can be separated in the frequency domain of the measurement signal.

The invention relates to a microelectronic magnetic sensor device with at least one sensor unit on the microchip. Moreover, it relates to the use of such a sensor device.

From the WO 2005/010543 A1 and WO 2005/010542 A2 (which are incorporated into the present application by reference) a microelectronic magnetic sensor device is known which may for example be used in a microfluidic biosensor for the detection of molecules, e.g. biological molecules, labeled with magnetic beads. The microsensor device is provided with an array of sensor units comprising two excitation wires for the generation of a magnetic field and a Giant Magneto Resistance (GMR) for the detection of stray fields generated by magnetized beads. The signal of the GMR is then indicative of the number of the beads near the sensor unit.

When a magnetic sensor device of the aforementioned kind is realized on a microchip, at least six bonding pins are needed to connect each sensor unit individually to external circuits (four pins for the two excitation wires, two pins for the GMR). The number of available pins on a microchip therefore restricts the number of possible sensor units.

Based on this situation it was an object of the present invention to provide a magnetic sensor device that is particularly suited for a realization with a microchip comprising a plurality of sensor units.

This objective is achieved by a microelectronic magnetic sensor device according to claim 1 and a use according to claim 16. Preferred embodiments are disclosed in the dependent claims.

The microelectronic magnetic sensor device according to the present invention comprises the following components:
a) At least one sensor unit which comprises at least one magnetic field generator for generating a magnetic excitation field in an adjacent investigation region (e.g. a sample chamber in which a sample fluid can be provided). The sensor unit further comprises at least one magnetic sensor element that is associated to the aforementioned magnetic field generator in the sense that it is in the reach of effects caused by the magnetic field of the magnetic field generator. The magnetic field generator may for example be realized by one or more conductor wires connected in series or in parallel. The magnetic sensor element may particularly comprise a Hall sensor or a magneto-resistive element like a GMR (Giant Magneto Resistance), a TMR (Tunnel Magneto Resistance), or an AMR (Anisotropic Magneto Resistance) element.
b) A power supply unit for providing a driving current for the aforementioned sensor unit, wherein said current is needed by the magnetic field generator and the magnetic sensor element to execute their functions. The driving current preferably comprises a first frequency and a different second frequency in its Fourier spectrum which allow to detect and compensate certain parasitic coupling effects in the measurement signals.
c) A coupling circuit for connecting the magnetic field generator and the magnetic sensor element of the sensor unit via (not more than) two connecting terminals to the power supply unit. In this context, the term “connecting terminal” shall in general denote any component in a circuit through which the whole driving current flows, for example a region where external wires are bonded to contact pads.

The proposed microelectronic magnetic sensor device has the advantage that the multi-component sensor unit and the power supply unit are linked via just two terminals, which makes this design particularly suited for hardware-realizations in which there is a bottleneck in the number of available connections.

The microelectronic magnetic sensor device will typically comprise a plurality of the described magnetic sensor units, because in this case the reduced number of just two connecting terminals per sensor unit is particularly needed to restrict the total number of terminals to reasonable values. The sensor units are preferably arranged in an array, e.g. a regular, planar matrix pattern.

In the aforementioned case, there might be one associated power supply unit for each sensor unit. Preferably, the number of power supply units is however smaller than the number of sensor units, and the coupling circuit comprises selection components (e.g. switches and a matrix structure) for selectively connecting sensor units to power supply units. The coupling circuit thus provides a multiplexing function for sharing the smaller number of power supply units (or even just one power supply unit) between the larger number of sensor units. If the selection components are realized on the sensor side of the connecting terminals, the total number of said terminals is favorably determined by the smaller number of power supply units.

The one or more sensor units of the microelectronic magnetic sensor device are preferably realized on one microelectronic chip, i.e. in one (semiconductor) substrate. In this case it is preferred that the connecting terminals are realized as bonding pins of said chip, because the number of such pins is usually limited for reasons of space.

If the magnetic field generator and/or the magnetic sensor element are realized as an integrated circuit on a substrate, the components of the coupling circuit may be disposed on or in the same substrate, in a molded interconnection device, on a connected signal processing IC, in a flex and/or in flex connector. Of course various components of the coupling circuit can also be distributed over the mentioned parts.

In a further development of the invention, the coupling circuit comprises components to couple the magnetic field generator and the magnetic sensor element to each other in an inductive and/or capacitive way. Such a coupling typically comprises a frequency dependent distribution of the driving current between the magnetic field generator and the magnetic sensor element which is desirable in terms of a later signal evaluation.

The magnetic field generator and the sensor element are preferably connected in parallel strands or paths to the connecting terminals. The driving current that flows through the connecting terminals will then be distributed to the two parallel paths according to their impedance.

In the aforementioned case, at least one of the two paths may comprise additional passive electronic components like capacitors, inductors and/or resistances that affect the distribution of the driving current between the two paths. The path that comprises the magnetic field generator may for example further comprise a capacitor connected in series or in parallel to the magnetic field generator.

The aforementioned capacitor may be realized by a stack of at least two metal (e.g. gold) layers that are separated by intermediate insulator layers and that are disposed on top of the magnetic field generator and/or of the magnetic sensor element. Thus the area that is available above the sensor unit can be exploited for the arrangement of the capacitor.

An evaluation unit is typically coupled to the magnetic sensor element for processing the measurement signals that are generated by said element and for extracting the desired information from them (e.g. the number of magnetized particles near the sensor unit). The evaluation unit may for example be realized by an integrated circuit in the same substrate as the sensor unit.

In a preferred embodiment, the evaluation unit is coupled to the magnetic sensor element via the two connecting terminals. In this case the evaluation unit is typically realized as an external module of the magnetic sensor device, i.e. it is not integrated on the same microchip as the sensor unit(s). By using the same two connecting terminals for the connection of both the power supply unit and the evaluation unit, the number of bonding pins can be further minimized.

In the aforementioned case, the evaluation unit may optionally be coupled to the connecting terminals via a filter component, e.g. an inductor, to select a certain frequency range that is passed on to the evaluation unit.

The evaluation unit preferably comprises components for processing selected frequencies of the measurement signals, as the relevant information can usually be separated from parasitic signal components in the frequency domain.

The power supply unit comprises in an optional embodiment of the invention a first current source for generating a first component of the driving current that has a first frequency, and a second current source for generating a second component of the driving current that has a second frequency, wherein said current sources may particularly be constant current sources. The resulting driving current will comprise at least two frequencies that help to separate the desired information in the measurement signals from parasitic components.

The invention further relates to the use of the microelectronic magnetic sensor device described above for molecular diagnostics, biological sample analysis, and/or chemical sample analysis, particularly the detection of small molecules. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

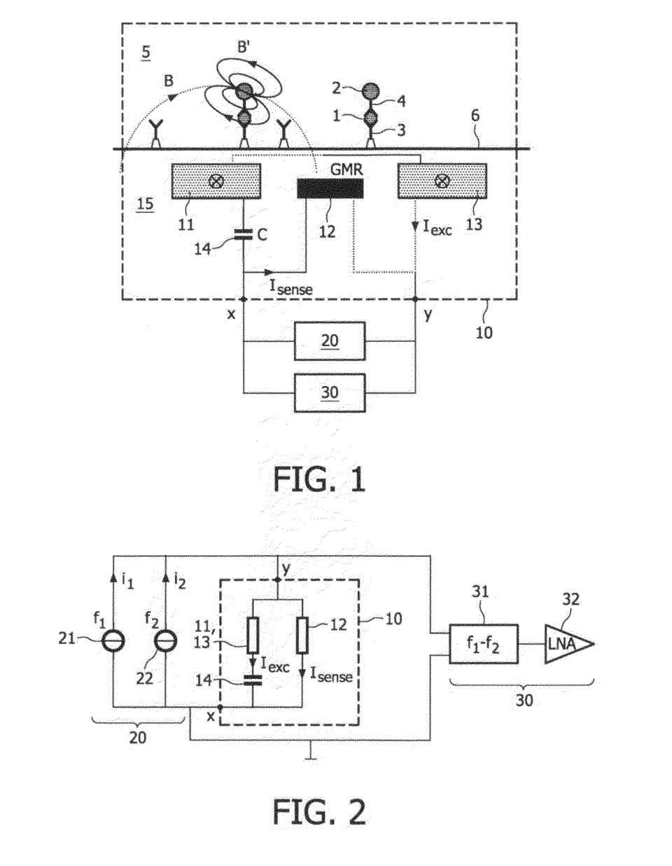

FIG. 1 shows schematically one sensor unit of a microelectronic magnetic sensor device according to a first embodiment of the present invention;

FIG. 2 shows the circuit diagram of the sensor device of FIG. 1;

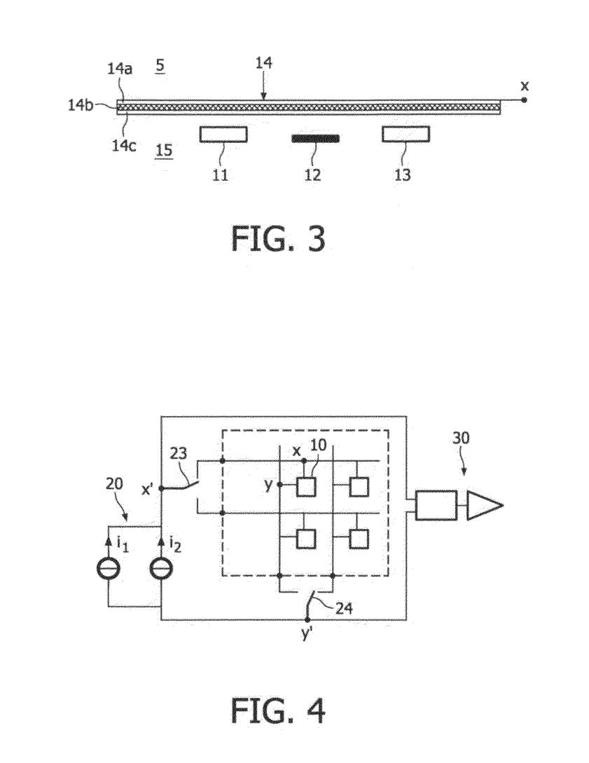

FIG. 3 shows schematically the realization of a capacitor on a sensor chip;

FIG. 4 shows the circuit diagram of a second embodiment of a sensor device, wherein the sensor units are coupled via a matrix structure to external components;

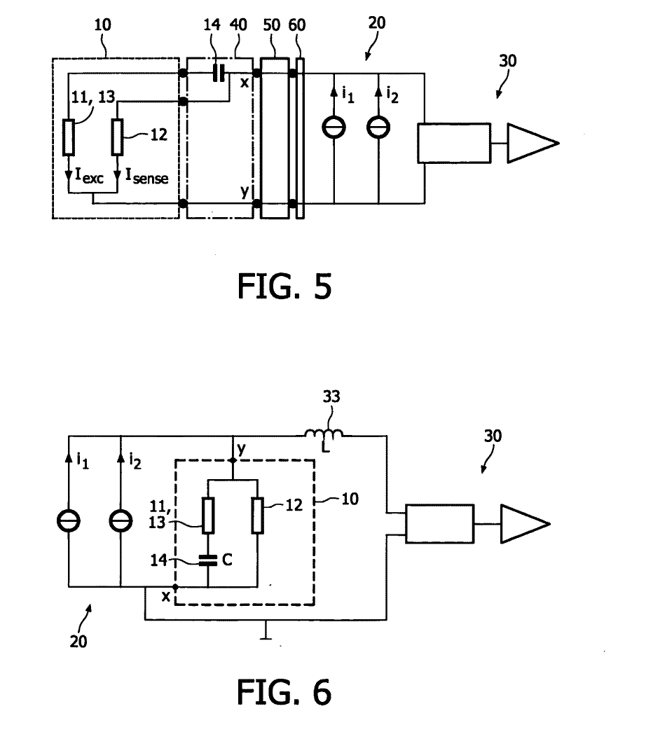

FIG. 5 shows the arrangement of passive components in a molded interconnection device (MID);

FIG. 6 shows the circuit diagram of a third embodiment of a sensor device, wherein an inductor is coupled between the sensor and the evaluation unit;

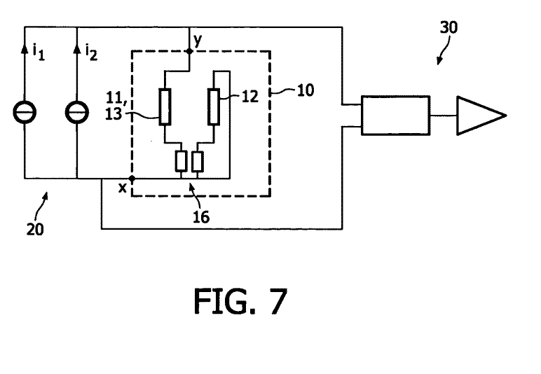

FIG. 7 shows the circuit diagram of a fourth embodiment of a sensor device, wherein the magnetic field generator and the magnetic sensor element are inductively coupled.

Like reference numbers in the Figures refer to identical or similar components.

FIG. 1 illustrates the principle of a single sensor unit 10 for the detection of superparamagnetic beads 2. A microelectronic (bio-)sensor device consisting of an array of (e.g. 100) such sensor units 10 may be used to simultaneously measure the concentration of a large number of different target molecules 1 (e.g. protein, DNA, amino acids, drugs of abuse) in a solution (e.g. blood or saliva) that is provided in a sample chamber 5. In one possible example of a binding scheme, the so-called “sandwich assay”, this is achieved by providing a binding surface 6 on a substrate 15 with first antibodies 3 to which the target molecules 1 may bind. Superparamagnetic beads 2 carrying second antibodies 4 may then attach to the bound target molecules 1. A total current I_{exc} flowing in series through the parallel excitation wires 11 and 13 of the sensor unit 10 generates a magnetic excitation field B, which then magnetizes the super-paramagnetic beads 2. The reaction field B′ from the superparamagnetic beads 2 introduces an in-plane magnetization component in the GMR 12 of the sensor unit 10, which results in a measurable resistance change that is sensed via a sensor current Iₛₑₙₛₑ. The mentioned currents Iₑₓₑ, Iₛₑₙₛₑ are supplied by a power supply unit 20.

If the sensor unit 10 as it has been described until now shall be connected to external modules like the power supply unit 20 and/or a signal evaluation unit 30, two terminals are in principle needed for each of its components, i.e. the first magnetic excitation wire 11, the second magnetic excitation wire 13, and the GMR sensor 12, and an additional terminal is needed for ground. A total number of seven pins is therefore needed if each sensor unit on a biochip shall be individually addressable. A biochip containing for example four sensor units thus requires 28 bonding pins of 32 pins that are typically available on a chip. The application of still more sensor units on one chip requires correspondingly more connections to interface all units to a reader device. The number of connections used for the interface should however on the other hand be minimized for the following reasons:
The area of the biochip should be optimized towards effective sensor area, without wasting area for bond pads that typically have a size of 100×100 μm.
Smaller chips cost less as chip cost is proportional to chip area.
A simple interface is less expensive and is in general more robust (less connections).

It is therefore desirable to connect a maximal number of sensor units to external reader/driving modules via a limited number of pins. Hence wiring schemes are looked for that maximize the number of sensor units for a given number of pins, or conversely, that minimize the number of pins used for connecting a given number of sensor units, wherein the sensor units are typically located on a disposable cartridge.

The solution proposed here comprises electrically coupling the magnetic field generating and the magnetic field sensing wires together. A non-linear two-port will then appear due to the multiplying behavior of the GMR element 12. The amplitude of the harmonic and inter-modulation components in the resulting measuring signals is then indicative to the in-plane magnetic field in the GMR sensor. As will be shown below, it will thus be possible that N pins can individually address M=(N/2)² sensor units due to the fact that each sensor unit is reduced to a (non-linear) two-port. The 32 pin chips mentioned above may therefore address 256 individual sensor units.

FIG. 1 and the corresponding circuit diagram of FIG. 2 show a particular realization of the aforementioned concepts. It comprises:
connecting the two magnetic excitation wires 11 and 13 in series (indicated in FIG. 1 by the dotted lines, which shall lie behind the drawing plane and be connected to the rear ends of the wires) to two particular connecting terminals x and y;
coupling a capacitor (C) 14 in the aforementioned excitation-wire path between the terminals x and y;
connecting also the GMR sensor 12 to the connecting terminals x and y.

Outside the chip, the power supply unit 20 and the evaluation unit 30 are connected in parallel to the connecting terminals x and y. Access to the integrated components 11, 12, 13 of the sensor unit 10 is therefore provided via only two connecting terminals (i.e. bonding pins) x and y.

The power supply unit 20 comprises two current sources 21 and 22 connected in parallel that provide a first current i₁ of a first frequency f₁ and a second current i₂ of a second frequency f₂, respectively, wherein it is assumed that f₁>f₂. The frequencies f₁ and f₂ generated by the two current sources 21, 22 shall both be well above the corner frequency of the 1/f noise.

The evaluation unit 30 comprises (inter alia) a band pass filter 31 centered around the frequency difference (f₁−f₂) followed by a Low-Noise-Amplifier (LNA) 32 which amplifies the low frequency magnetic signal at frequency (f₁−f₂).

The sensor unit 10 thus comprises a capacitive AC-coupling between the field generating current wires 11, 13 and the GMR element 12. Said coupling may be achieved as shown by an on-chip integrated capacitor 14 as well as by a parasitic capacitance. The purpose of the coupling capacitor 14 is to prevent the low frequency (f₁−f₂) signal component from being attenuated by the low series resistance R_{exc} of the series-connected wires 11, 13 (a typical value of R_{exc} is about 20 ohm, while the resistance R_{GMR} of the GMR element is about 500 ohm) and to guarantee the proper division of the total supplied current (i₁+i₂) between the GMR element 12 and the excitation wires 11, 13.

The feasibility of the described concept can be made plausible as follows: If it is assumed that the two current sources 21, 22 supply an “excitation current” iᵢ=I₁·sin ω₁t and a “sense current” i₂=I₂·sin ω₂t (with ω₁=2π·f₁ and ω₂=2π·f₂; I₁, I₂=const.) and that in the simplified case f₁ and f₂ are both well above the corner frequency of the AC coupling (i.e. ω₁CRₑₓₑ≧4, ω₂CR_{exc}≧4 with C being the capacitance of the capacitor 14 and R_{exc} being the total resistance of the excitation wires 11 and 13 in series), then the total current (iᵢ+i₂) is divided across the GMR element 12 and the excitation wires 11, 13 according to

α=Iₛₑₙₛₑ/I_{exc}=R_{exc}/R_{GMR}=0.04

with R_{GMR} being the resistance of the GMR element 12. This fits well with the typical current operating conditions of the sensor, namely Iₛₑₙₛₑ=2 mA and I_{exc}=50 mA.

Furthermore, the GMR voltage U_{GMR} is proportional to Iₛₑₙₛₑ and the GMR resistance change (Ohm's law), which in turn is proportional to the magnetization of the beads, which is proportional to the excitation current I_{exc}. Therefore:

$${U}_{GMR} ∝ {I}_{sense} \cdot {I}_{exc} \\ ∝ ( α \cdot ( {i}_{1} + {i}_{2} ) / ( 1 + α ) ] \cdot [ ( {i}_{1} + {i}_{2} ) / ( 1 + α ) ] \\ ∝ {i}_{1}^{2} + 2 \cdot {i}_{1} {i}_{2} + {i}_{2}^{2} \\ ∝ {I}_{1}^{2} \cdot ( 1 - cos {ω}_{1} t ) / 2 + {I}_{1} {I}_{2} \cdot cos ( {ω}_{1} - {ω}_{2} ) t + {I}_{2}^{2} \cdot ( 1 - cos {ω}_{2} t ) / 2$$

As a result the desired low-frequency content at frequency (f₁−f₂) in the GMR voltage, which is virtually un-attenuated due to relatively high corner frequency of the AC coupling, is equal to

U_{GMR}∝I₁I₂·cos(ω₁−ω₂)t.

The required capacitor value C depends on the operating frequency and the required impedance level. To achieve a pole at frequency f₁=450 MHz, the required coupling capacitor must be equal to

$$C = \frac{1}{ω \cdot 2 {R}_{exc}} = \frac{1}{2 π \cdot 4.5 \cdot {10}^{8} \cdot 2 \cdot 10} F = 18 p F ,$$

which extends 2100 μm² in CMOS18 technology (assuming a two layer metal oxide with 8.2 fF/μm²). This is as large as the sensitive area of a typical sensor design (100×21 μm).

FIG. 3 shows in this respect schematically how the coupling capacitor 14 can be realized on the sensitive chip surface above the sensor unit 10. The capacitor 14 consists in the shown example of two parallel Au-layers 14a,14c separated by an intermediate thin oxide layer 14b. The top (immobilization) gold-layer is grounded in order to avoid undesired effects on the biochemical assay. Multiple stacked metal/oxide layers may reduce the required area further.

In order to limit the influence of the wire resistance on the desired magnetic signal, f₁ and f₂ are chosen such that

$$\frac{1}{( {ω}_{1} - {ω}_{2} ) C} \geq 10 \cdot {R}_{GMR} .$$

In another variant of the described embodiment only the first frequency f₁ is chosen near or above the corner frequency of the AC-coupling. As a result the AC-coupling blocks the sense current i₂ so that it flows mainly through the GMR element 12. The excitation current i₁ is divided across the GMR element 12 and the excitation wires 11, 13, hence I_{exc}=0.96·i₁ and Iₛₑₙₛₑ=0.04·i₁+i₂. This approach is advantageous because it limits the dominating power dissipation in the field generating wires.

The design of FIGS. 1 and 2 can be used to connect each sensor unit 10 individually to one associated power supply unit 20 and/or evaluation unit 30. Preferably, a small number of power supply units and/or evaluation units is shared between a larger number of sensor units 10 arranged in an array on a microchip. This can for example be realized by connecting each two-terminal sensor unit 10 in the well-known passive matrix structure, where the pin count N for M sensor units 10 reduces to N=2\sqrt{M}.

FIG. 4 shows the aforementioned layout, in which each sensor unit 10 comprises one connecting terminal x and one connecting terminal y. The y-terminals of all sensor units that lie in the same column of the array of sensor units 10 are connected to the same vertical line, and all x-terminals of sensor units that lie in the same row of the array of sensor units 10 are connected to the same horizontal line. Multiplexing switches 23, 24 can then be used to connect the horizontal and vertical lines selectively to the outputs x′ and y′, respectively, of the power supply unit 20 (which are simultaneously the inputs of the evaluation unit 30). The sensor unit 10 for which both the x- and the y-terminal are connected to the outputs x′ and y′, i.e. the sensor unit at the crossing point of the selected row and the selected column, will be read out. It should be noted that the two outputs x′ and y′ as well as the connecting terminals x and y (per sensor unit) can be considered as “connecting terminals” in the sense of the present application, because the power supplied to the whole sensor unit 10 flows through them.

The capacitor 14 was assumed in the previous embodiments to be integrated in the same substrate 15 as the sensor unit 10. It may however also be located in other modules. FIG. 5 shows in this respect an embodiment in which the capacitive coupling is not on the sensor die, but e.g. on the Molded Interconnection Device (MID) 40. The advantage of this approach is the small number of flex-connections between the flex 50 and the evaluation unit 20, which enables the implementation of a robust (use many times) flex connector 60. This is important for a disposable sensor. Furthermore, large coupling capacitors (enabling low operating frequencies) are easy to implement in discrete components. This approach therefore reduces the complexity of the multiplexing circuitry in the signal processing electronics.

In case there is not enough space on the MID 40, the coupling capacitor 14 might also be located on the signal processing board, on a (flip-chip) connected signal processing IC, or on the flex 50 (either in discrete components or by an appropriate flex design to introduce capacitive coupling).

FIG. 6 shows a variant of the circuit of FIG. 2, in which an external inductor 33 is located between the evaluation unit 30 and one of the connecting terminals x, y, e.g. in a reader station comprising the evaluation unit. In this way, an LC resonance circuit is realized that helps to reduce the operating frequency and/or the required capacitor area. A quality factor Q=10 at resonance frequency f₁=45 MHz can for example be realized on 2100 μm² capacitor area (18 pF). Typical values of the frequencies are f₁=10 MHz and f₂=10.05 MHz.

FIG. 7 shows the circuit diagram of another embodiment of the invention, in which the GMR sensor 12 is inductively coupled to the excitation wires 11, 13, for example by two parallel leads or coils 16. Said inductive coupling may be (parasitic) present on the sensor die, the MID, the flex, or the signal processing board. The operating frequencies (f₁−f₂, f₁, f₂) must be high enough to realize effective coupling. Obviously the same principle may be used for capacitive coupling, where the GMR is coupled to the wires by (parasitic) capacitive coupling anywhere between sensor and LNA.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A microelectronic magnetic sensor device, comprising
a) at least one sensor unit (10) with a magnetic field generator (11, 13) and an associated magnetic sensor element (12);
b) at least one power supply unit (20) for providing a driving current for the sensor unit (10);
c) a coupling circuit (14, 16, 23, 24, 40, 50, 60) for connecting the magnetic field generator (11, 13) and the magnetic sensor element (12) of the sensor unit (10) via two connecting terminals (x, y) to the power supply unit (20).

2. The microelectronic magnetic sensor device according to claim 1,
characterized in that it comprises a plurality of such sensor units (10).

3. The microelectronic magnetic sensor device according to claim 2,
characterized in that it comprises a smaller number of power supply units (20) than of sensor units (10), wherein the coupling circuit comprises selection components (23, 24) for selectively connecting sensor units (10) to power supply units (20).

4. The microelectronic magnetic sensor device according to claim 1,
characterized in that the connecting terminals (x, y) are realized as bonding pins of a microelectronic chip that comprises the sensor unit (10).

5. The microelectronic magnetic sensor device according to claim 1,
characterized in that at least one component (14) of the coupling circuit is disposed on or in the same substrate (15) as the magnetic field generator (11, 13) and/or the magnetic sensor element (12), in a molded interconnection device (40), on a connected signal processing IC, in a flex (50), and/or in a flex connector (60).

6. The microelectronic magnetic sensor device according to claim 1,
characterized in that the coupling circuit comprises components (16) to couple the magnetic field generator (11, 13) and the magnetic sensor element (12) to each other in an inductive and/or in a capacitive way.

7. The microelectronic magnetic sensor device according to claim 1,
characterized in that the magnetic field generator (11, 13) and the magnetic sensor element (12) are connected in parallel paths to the connecting terminals (x, y).

8. The microelectronic magnetic sensor device according to claim 7,
characterized in that at least one of the paths comprises a passive electronic component, particularly a capacitor (14).

9. The microelectronic magnetic sensor device according to claim 8,
characterized in that the capacitor (14) is composed of at least two metal layers, preferably Au-layers (14a, 14c), separated by an insulating layer (14b) on top of the magnetic field generator (11, 13) and/or the magnetic sensor element (12).

10. The microelectronic magnetic sensor device according to claim 1,
characterized in that it comprises an evaluation unit (30) that is coupled to the magnetic sensor element (12) for processing its measurement signals.

11. The microelectronic magnetic sensor device according to claim 10,
characterized in that the evaluation unit (30) is coupled to the magnetic sensor element (12) via the connecting terminals (x, y).

12. The microelectronic magnetic sensor device according to claim 10,
characterized in that the evaluation unit (30) is coupled to the connecting terminals (x, y) via a filter component, particularly an inductor (33).

13. The microelectronic magnetic sensor device according to claim 10,
characterized in that the evaluation unit (30) comprises components (31) for processing selected frequencies of the measurement signals.

14. The microelectronic magnetic sensor device according to claim 1,
characterized in that the power supply unit (20) comprises a first current source (21) for generating a first component (i₁) of the driving current having a first frequency f₁ and a second current source (22) for generating a second component (i₂) of the driving current having a second frequency f₂.

15. The microelectronic magnetic sensor device according to claim 1,
characterized in that the magnetic sensor element comprises a Hall sensor or a magneto-resistive element like a GMR (12), an AMR, or a TMR element.

16. Use of the microelectronic magnetic sensor device according to claim 1 for molecular diagnostics, biological sample analysis, and/or chemical sample analysis, particularly the detection of small molecules.
